(19) United States
(12) Patent Application Publication
(10) Pub. No.: US 2011/0174371 A1
(43) Pub. Date: Jul. 21, 2011

(54) METHOD FOR LIMITING EPITAXIAL GROWTH IN A PHOTOELECTRIC DEVICE WITH HETEROJUNCTIONS AND PHOTOELECTRIC DEVICE

(75) Inventors: Sara Olibet, Winterthur (CH); Christian Monachon, Rivaz (CH); Jérôme Damon-Lacoste, Antony (FR); Christophe Ballif, Neuchatel (CH)

(73) Assignee: UNIVERSITÉ DE NEUCHÂTEL, Neuchâtel (CH)

(21) Appl. No.: 13/061,584

(22) PCT Filed: Aug. 31, 2009
(86) PCT No.: PCT/EP2009/061223

§ 371 Date: Mar. 30, 2011

(30) Foreign Application Priority Data
Sep. 1, 2008 (EP) 08163425.5

(51) Int. Cl. H01L 31/0236; H01L 31/0376; H01L 31/0368

(52) U.S. Cl. 136/256; 438/96; 438/97; 257/E31.048; 257/E31.045

(57) ABSTRACT

A method for limiting epitaxial growth in a photoelectric device with heterojunctions including a crystalline silicon substrate and at least one layer of amorphous or microcrystalline silicon, wherein the method is characterised in that it includes the step of texturing the crystalline silicon surface.

### TECHNICAL FIELD

The present invention relates to the field of photoelectric devices. It more particularly relates to a method for limiting epitaxial growth in a photoelectric device with heterojunctions comprising a crystalline silicon substrate. The present invention also relates to said photoelectric device.

The present invention finds a particularly interesting application for making photovoltaic cells intended for producing electric energy, but it also applies more generally to any structure in which light radiation is converted into an electric signal, such as photodetectors.

### BACKGROUND OF THE INVENTION

In a known way, the photoelectric devices with heterojunctions comprise a crystalline silicon substrate covered with a layer or several layers of amorphous silicon or microcrystalline silicon. Such a device may thereby comprise in this order, a crystalline silicon substrate, a hydrogenated amorphous silicon layer and a hydrogenated microcrystalline silicon layer.

In order to improve performances, and in particular the output current of devices with heterojunctions comprising a crystalline silicon substrate, it is known how to modify the texturization of the crystalline silicon substrate by forming many pyramid-shaped irregular sections with an anisotropic etching method, as this is described in U.S. Pat. No. 4,137,123. The anisotropic wet chemical etching method in an alkaline medium used for forming the pyramids has the consequence of producing valleys, the bottom of which have sharp edges. The area connecting the base of the pyramids is called a valley.

In certain publications, notably in U.S. Pat. No. 6,207,890, it was observed that, in these valleys having sharp edges, the deposit of hydrogenated amorphous silicon is not sufficiently thick, which has the drawback of reducing the open circuit voltage (V_{oc}) and the filling factor (FF) of solar cells with heterojunctions with a crystalline silicon substrate. U.S. Pat. No. 6,207,890 solves this problem by proposing that isotropic etching of the substrate be achieved in order to round off the bottom of the valleys, which has the effect of being able to deposit an amorphous or microcrystalline silicone layer of uniform thickness with a plasma enhanced chemical vapor deposition method (PECVD).

By using suitable deposition conditions (PECVD) known to one skilled in the art, it is possible to obtain cells with heterojunctions in which the amorphous or microcrystalline silicon layer deposited on the crystalline silicon substrate has constant thickness, even if said substrate has a pyramidal texture following the use of an anisotropic etching method. However, as shown in FIG. 1, an epitaxy process was observed in the valleys with sharp edges of the crystalline silicon substrate during the growth of hydrogenated amorphous or crystalline silicon. Indeed, the amorphous silicon and microcrystalline silicon layers, the interfaces of which are well discernible on the facets of the pyramids, become indiscernible in the sharp-edged valleys of the pyramids formed on the crystalline silicon substrate. This local epitaxial growth has the drawback of reducing the open circuit voltage (V_{oc}) of solar heterojunction cells with a crystalline silicon substrate and therefore their yield.

An object of the present invention is therefore to overcome this drawback, by proposing a method with which local epitaxial growth may be reduced and the influence of the epitaxy may be limited in a photoelectric device with heterojunctions, comprising a crystalline silicon substrate having a pyramidal texture, during the growth of hydrogenated amorphous or microcrystalline silicon.

### SUMMARY OF THE INVENTION

For this purpose, and according to the present invention, a method is proposed for limiting epitaxial growth in a photoelectric device with heterojunctions comprising a crystalline silicon substrate and at least one amorphous or microcrystalline silicon layer, this method being characterized in that it comprises a step for texturization of the crystalline silicon surface.

In a first alternative embodiment, called alternative A, said texturization step comprises the formation of pyramids on the crystalline silicon substrate, said pyramids having a base for which the dimensions are strictly greater than 5 μm.

According to a second alternative embodiment, called alternative B, the texturization step comprises the formation of pyramids on the crystalline silicon substrate, said pyramids having a regular layout such that less than 20% of the crystalline silicon surface is covered with pyramids having sub-micrometric dimensions and more than at least half of the crystalline silicon surface is covered with pyramids for which the dimensions b of the base are such that bε b̅±5 μm, wherein b̅ is the average value of the dimensions b of the base of the pyramids, and wherein b is strictly greater than 1 μm.

According to a third alternative embodiment, called alternative C, the texturization step comprises the formation of pyramid valleys on the crystalline silicon substrate, said valleys having a rounded bottom.

The present invention also relates to a photoelectric device with heterojunctions comprising a crystalline silicon substrate in which the epitaxy process during the growth of hydrogenated amorphous or microcrystalline silicon on said crystalline silicon substrate was limited according to one of the first two methods A and B described above.

### BRIEF DESCRIPTION OF THE DRAWINGS

Other features of the present invention will become more clearly apparent upon reading the description which follows, made with reference to the appended drawing, wherein:

FIG. 1 is a micrograph obtained with a transmission electron microscope showing the epitaxial growth in a photoelectric device with heterojunctions of the prior art, comprising an amorphous silicon layer and a microcrystalline silicon layer on a crystalline silicon substrate having pyramids, the valleys of which are with sharp edges,

FIG. 2 is a photograph showing a crystalline silicon substrate, the surface of which was textured according to step A of the method of the invention,

FIG. 3 is a photograph showing a crystalline silicon substrate, the surface of which was textured according to step B of the method of the invention, and

FIG. 4 is a micrograph obtained by a transmission electron microscope showing the limitation of the epitaxial growth in a photoelectric device with heterojunctions comprising an amorphous silicon layer and a microcrystalline silicon layer on a crystalline silicon substrate textured according to the method combining the steps A, B and C of the invention.

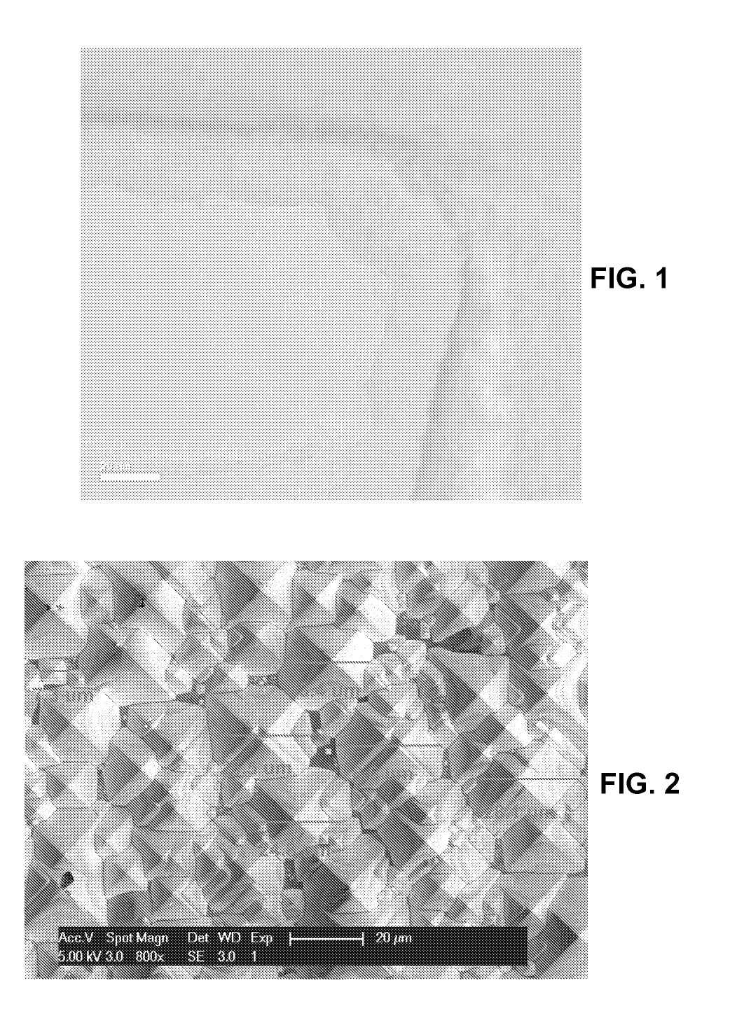

### DETAILED DESCRIPTION

According to the invention, the method for limiting epitaxial growth in a photoelectric device with heterojunctions comprising a crystalline silicon substrate and at least one microcrystalline or amorphous silicon layer, comprises a step for texturization of the crystalline silicon surface.

In a first alternative embodiment, called alternative A, said texturization step comprises the formation of pyramids on the crystalline silicon substrate, said pyramids having a base, the sides of which have dimensions strictly greater than 5 μm.

Preferably, the majority of the c-Si surface, i.e. strictly more than half, is covered with pyramids having a base, the sides of which have dimensions strictly greater than 5 μm. Preferably, the sides of the base of said pyramids have dimensions comprised between 5 μm and 25 μm, and more preferentially between 10 μm excluded and 20 μm. The formation of pyramids of large sizes allows reduction in the density of valleys per unit surface. The height h of the pyramids may trivially be related to the dimensions of the edges c of the base by the formula tan(54.74)=(2×h)/c. The size of the pyramids as well as their uniformity may be easily determined by scanning microscopy image processing or by stereoscopic reconstruction (Kuchler et al, STEREOSCOPIC RECONSTRUCTION OF RANDOMLY TEXTURED SILICON SURFACES, 17^{th} European Photovoltaic Solar Energy Conference, Oct. 22^{nd} to 26^{th}, 2001, Munich).

The pyramids may be formed by anisotropic etching, for example with a KOH/IPA mixture or with a NaOH or TMAH solution (with or without IPA) or a mixture of Na₂CO₃/NaHCO₃. Preferably a KOH solution at 2-3 weight % IPA concentrations and at 6-8 volume % water concentrations and etching times of 5-40 minutes at 80° C. are used for this anisotropic etching. The size of the pyramids increases with the etching time and strongly depends on the type and level of doping of the selected silicon substrate. The reduction in the KOH concentration, the reduction in the IPA concentration or the increase in the etching time promote large pyramids. These parameters will be adjusted depending on the desired sizes of pyramids. Notably, the etching time will be increased until the desired pyramid sizes are obtained. One skilled in the art controls the sizes obtained by the means indicated above in order to determine the parameters of anisotropic etching.

FIG. 2 illustrates a crystalline silicon substrate, the surface of which was textured according to the step A. The obtained pyramids have a base, the sides of which are on the average greater than 20 μm, with good uniformity.

In a second alternative embodiment, called alternative B, said texturization step comprises the formation of pyramids on the crystalline silicon substrate, said pyramids having a regular layout defined by a low presence of sub-micrometric pyramids (less than 20% of the surface of the c-Si is covered with pyramids having sub-micrometric dimensions) and more than at least half of the surface of the c-Si is covered with pyramids, the dimensions b of which the sides of the base are such that bε b̅±5 μm, wherein b̅ is the average value of the dimensions b of the base of the pyramids, and wherein b is strictly greater than 1 μm. Preferentially, less than 10% of the surface of the c-Si is covered with pyramids having sub-micrometric dimensions and more than ⅔ of the surface of the c-Si is covered with pyramids, for which the dimensions b of the sides of the base are such that bε b̅±2.5 μm. With this step it is possible to reduce the density of valleys per unit surface, by limiting the sub-micrometric texture elements on the one hand and by limiting the nested pyramids on the other hand.

With respect to option A, option B is therefore characterized by better uniformity of the sizes of the pyramids, which may, unlike option A, be smaller than 5 μm, but with a small proportion of pyramids having sub-micrometric sizes. FIG. 3 illustrates a crystalline silicon substrate, the surface of which was textured according to the step B. The pyramids are smaller and have a base, the sides of which are on the average less than 5 μm and there are few pyramids with sub-micrometric dimensions.

The average dimensions b of the sides of the base of the pyramids are preferably comprised between 3 μm and 25 μm, and more preferentially between 5 μm excluded and 20 μm.

Step B may be achieved by anisotropic etching, for example with a KOH/IPA mixture with attention paid to the uniformity of the temperature (for example according to the method described in W. Sparber et al. <<Comparison of Texturing Methods for Monocrystalline Silicon Solar Cells using KOH and Na₂CO₃>>”, Proc. of the 3^{rd} World Conf. on Photovoltaic, Osaka, 2003) or with a NaOH or TMAH solution (with or without IPA) or a Na₂COₓ/NaHCO₃ mixture. The parameters of the etching method are adapted depending on the initial surface condition of the crystalline silicon substrate. Preferably a KOH/IPA solution similar to the one of the method used for option A will be used, while being aware that a reduction in the concentration of KOH, a reduction in the concentration of IPA or an increase in the etching time promote large pyramids. Therefore for alternative B, generally shorter etching times will therefore be used than the ones used for alternative A if it is desired to obtain pyramids of small sizes. The uniformity of the temperature and of the stirring are primordial for this option B in order to have better uniformity in the size of the pyramids.

In a third alternative embodiment, called alternative C, said texturization step comprises the formation of pyramids and valleys on the crystalline silicon substrate, said valleys having a rounded bottom.

The rounded bottom of the valleys has a radius of curvature greater than 0.005 μm and preferably comprised between 0.05 μm and 15 μm. At least 50% of the pyramids should have such a rounded bottom, preferentially at least 75% of them.

This step may be achieved by isotropic etching for example with a so-called CP133 solution i.e. a mixture of HF (50% in deionized H₂O), of HNO₃ (100% fuming acid) and of CH₃COOH (100%), in proportions of 1:3:3. A solution containing only HF and HNO₃ may also be used. The treatment times are preferably comprised between 3 and 20 seconds and also depend on the selected Si substrate.

Depending on the initial surface condition of the crystalline silicon substrate, this step may be broken down into two steps, first of all the formation of irregular pyramids on a crystalline silicon substrate for example according to the method described in the publication of W. Sparber et al. <<Comparison of Texturing Methods for Monocrystalline Silicon Solar Cells using KOH and Na₂CO₃>>, Proc. of the 3^{rd} World Conf. on Photovoltaic, Osaka, 2003 and then the rounding of the bottom of the valleys by isotropic etching.

The methods for forming pyramids are controlled by one skilled in the art who knows how to adapt the parameters of these different methods in order to obtain pyramids having the sought characteristics according to either one of the alternatives. The invention is not based on the methods for forming the pyramids but on the use of the dimensions and of the distribution of these pyramids for reducing local epitaxial growth during the growth of hydrogenated amorphous or microcrystalline silicon on a crystalline silicon substrate having a pyramidal texture in a photoelectric device with heterojunctions. Notably, one skilled in the art may refer to the publication of W Sparber, O. Schultz, D. Biro, G. Emanuel, R. Preu, A. Poddey and D. Borchert, “Comparison of Texturing Methods for Monocrystalline Silicon Solar Cells Using KOH and Na₂CO₃”, Proc. of the 3^{rd} World Conf. on Photovoltaic, Osaka, 2003. Further, temperature and stirring uniformity are significant parameters for obtaining a uniform texture.

The three alternative embodiments A, B and C may be combined with each other, with two or three of them.

Thus, it is possible to apply the method of the invention by separately applying either one of the alternatives A, B or C, or by combining the alternatives A and B, A and C, B and C, or A, B and C. The A and B combination steps may be achieved in a single step.

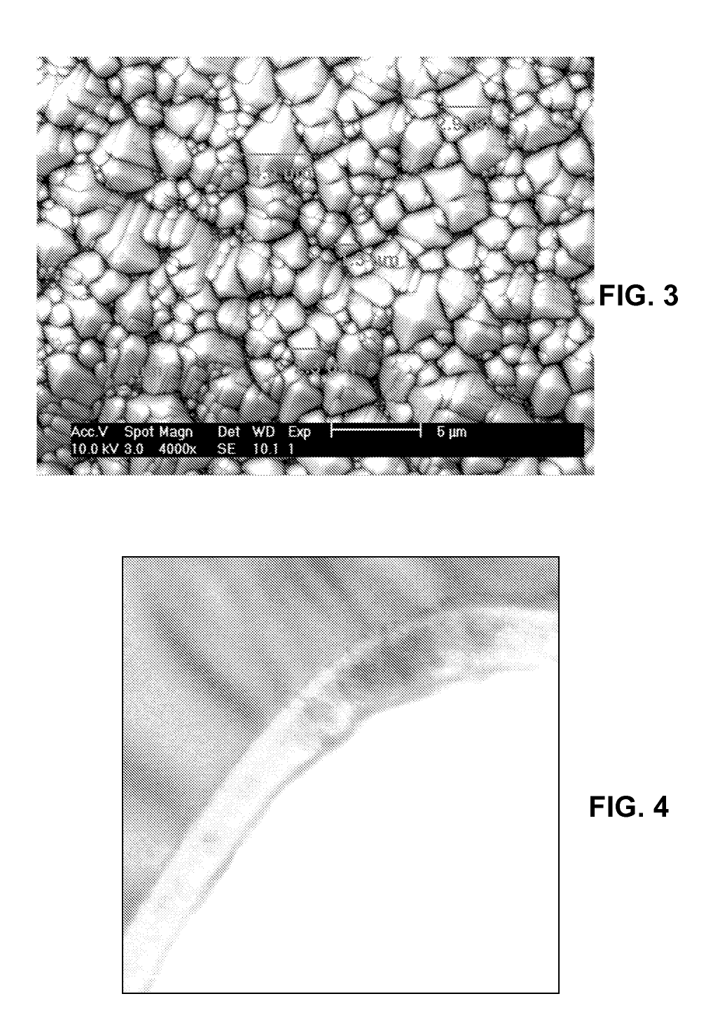

FIG. 4 illustrates a micrograph obtained with a transmission electron microscope showing the limitation of the epitaxial growth in a photoelectric device with heterojunctions comprising an amorphous silicon layer and a microcrystalline silicon layer on a textured crystalline silicon substrate according to the method combining the steps A, B and C of the invention. The interfaces between the crystalline silicon layers the amorphous silicon layers and the microcrystalline silicon layers are clearly seen in this figure, which shows a reduction in epitaxial growth.

After the step for texturization of the crystalline silicon surface, at least one amorphous or microcrystalline silicon layer is deposited on the thereby textured crystalline silicon substrate in order to obtain a photoelectric device with heterojunctions according to techniques known to one skilled in the art.

The present invention relates to a photoelectric device with heterojunctions comprising a crystalline silicon substrate wherein the epitaxy process during the growth of hydrogenated amorphous or microcrystalline silicon on said crystalline silicon substrate was limited according to one of the first two methods A and B described above. According to a first alternative embodiment, such a device may comprise a textured crystalline silicon substrate having at its surface pyramids having a base, the sides of which have dimensions strictly greater than 5 μm, preferably comprised between 5 μm and 25 μm and more preferentially between 10 μm and 20 μm.

According to another alternative embodiment, the photoelectric device of the invention comprises a textured crystalline silicon substrate having at its surface pyramids with a regular layout defined by a low presence of sub-micrometric pyramids (less than 20% of the surface of the c-Si is covered with pyramids having sub-micrometric dimensions) and more than at least half of the surface of the c-Si is covered with pyramids, for which the dimensions b of the sides of the base are such that bε b̅±5 μm, wherein b̅ is the average value of the dimensions b of the base of the pyramids, and wherein b is strictly greater than 1 μm. Preferentially, less than 10% of the surface of the c-Si is covered with pyramids having sub-micrometric dimensions and more than ⅔ of the surface of the c-Si is covered with pyramids, for which the dimensions b of the base are such that bε b̅±2.5 μm.

Further, said thereby textured crystalline silicon substrate according to either one of said alternatives may comprise valleys having a rounded bottom. The rounded bottom of the valleys may have a radius of curvature greater than 0.005 μm and preferably comprised between 0.05 μm and 15 μm. The rounded bottom of the valleys is obtained according to the method C described above.

Moreover, both alternatives defined above may be combined so as to obtain a device comprising a textured crystalline silicon substrate having at its surface pyramids with a base, the dimensions b of which are strictly greater than 5 μm and having a regular layout defined by a low presence of sub-micrometric pyramids (less than 20% of the surface of the c-Si is covered with pyramids having sub-micrometric dimensions) and more than at least half of the surface of the c-Si is covered with pyramids, for which the dimensions b of the base are such that bε b̅±5 μm. Preferentially, less than 10% of the surface of the c-Si is covered with pyramids having sub-micrometric dimensions and more than ⅔ of the surface of the c-Si is covered with pyramids, for which the dimensions b of the base are such that bε b̅±2.5 μm.

There again, said thereby textured crystalline silicon substrate may comprise valleys having a rounded bottom, as defined above.

Further, the step for rounding the bottom of the valleys also gives the possibility, if the isotropic etching time is controlled, of rounding the apex of the pyramids, by however controlling the process so as not to reduce the amount of trapped light. This allows improvement in the robustness of the solar cells during the assembling step. Indeed, rounding the apex of the pyramids allows a significant reduction in the mechanical defects during the assembling of the cells by reducing the number of apices of pyramids which may be broken, in particular when these apices are particularly pointed.

Thus, and according to a preferred alternative embodiment of the invention, a photoelectric device with heterojunctions is obtained, comprising a textured crystalline silicon substrate having at its surface pyramids and valleys, said pyramids having a base, the dimensions b of which are strictly greater than 5 μm and having a regular layout defined by a low presence of sub-micrometric pyramids (less than 20% of the surface of the c-Si is covered with pyramids having sub-micrometric dimensions) and more than at least half of the surface of the c-Si is covered with pyramids, for which the dimensions b of the base are such that bε b̅±5 μm. Preferentially, less than 10% of the surface of the c-Si is covered with pyramids having sub-micrometric dimensions and more than ⅔ of the surface of the c-Si is covered with pyramids, for which the dimensions b of the base are such that bε b̅±2.5 μm, and said valleys have a rounded bottom, the radius of curvature of which is greater than 0.005 μm and preferably comprised between 0.05 μm and 15 μm.

The thereby obtained devices according to the invention have yields which are greater than those of existing heterojunction devices.

### EXAMPLES

Three photovoltaic cells with heterojunctions are prepared by following steps A, B, A and B, and A, B and C for texturization of the crystalline silicon substrate.

The steps A and B are achieved according to the publication of W. Sparber, O. Schultz, D. Biro, G. Emanuel, R. Preu, A. Poddey and D. Borchert, “Comparision of Texturing Methods for Monocrystalline Silicon Solar Cells Using KOH and Na₂CO₃”, Proc. of the 3^{rd} World Conf. on Photovoltaic, Osaka, 2003, in order to obtain the characteristics of the invention.

For step C, the substrate is soaked in an aqueous solution comprising 50% hydrogen fluoride (HF), nitric acid (100% fuming acid) and 100% acetic acid (CH₃COOH) in a ratio of 1:3:3, for about 5 seconds for a freshly prepared solution or about 1 minute in the other cases.

As a comparison, a photovoltaic cell is made, the crystalline silicone substrate of which is formed with small (dimensions of the base of less than 5 μm) and irregular pyramids prepared according to the method described in the publication of King et al. “Experimental Optimization of an Anisotropic etching process for random texturization of silicon solar cells”, 22^{nd} IEEE PSC 1991 and without paying attention to either the size or to the regularity of the pyramids.

The following parameters are measured: the open circuit voltage (V_{oc}), the filling factor (FF), the short circuit current density (J_{sc}) and the yield according to the AM 1.5 standard.

The results are indicated in the table below.

| Examples | V_{oc} (mV) | FF (%) | J_{sc} (mA/cm²) | Yield (%) |
|---|---|---|---|---|
| Comparative | 601 | 68.4 | 34.5 | 14.2 |
| Step A | 631 | 72.9 | 34.6 | 15.5 |
| Step B | 618 | 69.5 | 34.6 | 14.9 |
| Steps A + B | 660 | 68.9 | 35.6 | 16.0 |
| Steps A + B + C | 700 | 67.0 | 36.5 | 17.0 |

The results of this table show that with the method according to the invention, the performances of photoelectric devices with heterojunctions are improved, in particular when the three steps A, B and C are combined.

1-22. (canceled)

23. A method for limiting epitaxial growth in a photoelectric device with heterojunctions comprising a crystalline silicon substrate and at least one amorphous or microcrystalline silicon layer, wherein it comprises a step for texturization of a surface of said crystalline silicon substrate.

24. The method according to claim 23, wherein said texturization step is a step A comprising the formation of pyramids on the crystalline silicon substrate, said pyramids having a base, the dimensions of which are strictly greater than 5 μm.

25. The method according to claim 24, wherein said texturization step A comprises the formation of pyramids on the crystalline silicon substrate, the majority of the surface of the crystalline silicon substrate being covered by pyramids, the dimensions of which are strictly greater than 5 μm.

26. The method according to claim 24, wherein the base of said pyramids has dimensions comprised between 5 μm excluded and 25 μm, and more preferentially between 10 μm and 20 μm.

27. The method according to claim 24, wherein said texturization step A of the surface of said crystalline silicon substrate is achieved by anisotropic etching.

28. The method according to claim 23, wherein said texturization step is a step B comprising the formation of pyramids on the crystalline silicon substrate, said pyramids having a regular layout such that less than 20% of the surface of the crystalline silicon is covered with pyramids having sub-micrometric dimensions and more than at least half of the surface of the crystalline silicon is covered with pyramids, for which the dimensions b of the base are such that bε b̅±5 μm, wherein b̅ is the average value of the dimensions b of the base of the pyramids, and b being strictly greater than 1 μm.

29. The method according to claim 28, wherein said texturization step B comprises the formation of pyramids on the crystalline silicon substrate, said pyramids having a regular layout such that less than 10% of the crystalline silicon surface is covered with pyramids having sub-micrometric dimensions and more than ⅔ of the surface of the crystalline silicon is covered with pyramids, the dimensions b of which of the base being such that bε b̅±2.5 μm.

30. The method according to claim 28, wherein said texturization step B of the surface of said crystalline silicon substrate is achieved by anisotropic etching.

31. The method according to claim 23, wherein said texturization step is a step C comprising the formation of pyramids and valleys on the crystalline silicon substrate, said valleys having a rounded bottom.

32. The method according to claim 31, wherein the rounded bottom of the valleys has a radius of curvature greater than 0.005 μm, preferably comprised between 0.005 μm and 15 μm.

33. The method according to claim 31, wherein at least 50% of said pyramids, preferentially at least 75% of said pyramids, are connected through a valley, the rounded bottom of which has a radius of curvature greater than 0.005 μm, preferably comprised between 0.05 μm and 15 μm.

34. The method according to claim 31, wherein said texturization step C of the surface of said crystalline silicon substrate is achieved by isotropic etching.

35. The method according to claim 31, wherein said texturization step C of the surface of said crystalline silicon substrate is broken down into two steps, that means, first of all, the formation of irregular pyramids on a crystalline silicon substrate achieved by anisotropic etching, and then the rounding of the bottom of the valleys by isotropic etching.

36. The method according to claim 31, wherein said step for texturization of the surface of the crystalline silicon substrate consists in a combination, with two or with three, of the texturization steps A, B and C, the texturization step A comprising the formation of pyramids on the crystalline silicon substrate, said pyramids having a base, the dimensions of which are strictly greater than 5 μm, the texturization step B comprising the formation of pyramids on the crystalline silicon substrate, said pyramids having a regular layout such that less than 20% of the surface of the crystalline silicon is covered with pyramids having sub-micrometric dimensions and more than at least half of the surface of the crystalline silicon is covered with pyramids, for which the dimensions b of the base are such that bε b̅±5 μm, wherein b̅ is the average value of the dimensions b of the base of the pyramids, and b being strictly greater than 1 μm, and the texturization C comprising the formation of pyramids and valleys on the crystalline silicon substrate, said valleys having a rounded bottom.

37. The method according to claim 36, wherein it comprises:
a step for texturization of the surface of the crystalline silicon substrate achieved by anisotropic etching in order to form at the surface of said crystalline silicon substrate pyramids having a base, the dimensions b of which are strictly greater than 5 μm, and having a regular layout such that less than 20% of the surface of the crystalline silicon is covered with pyramids having sub-micrometric dimensions and more than at least half of the surface of the crystalline silicon is covered with pyramids, for which the dimensions b of the base are such that bε b̅±5 μm, and
a step for texturization of the surface of the crystalline silicon substrate achieved by isotropic etching in order to obtain among said pyramids, valleys having a rounded bottom.

38. A photoelectric device with heterojunctions comprising a crystalline silicon substrate having a textured surface and at least one amorphous or microcrystalline silicon layer, wherein epitaxy has been limited during the growth of said amorphous or microcrystalline silicon on said crystalline silicon substrate, wherein said textured crystalline silicon substrate has at its surface pyramids having a base, the dimensions b of which are strictly greater than 5 μm, preferably comprised between 5 μm excluded and 25 μm, and more preferentially between 10 μm and 20 μm.

39. The device according to claim 38, characterized in that said pyramids further have a regular layout such that less than 20% of the surface of the crystalline silicon is covered with pyramids having sub-micrometric dimensions and more than at least half of the surface of the crystalline silicon is covered with pyramids, for which the dimensions b of the base are such that bε b̅±5 μm, wherein b̅ is the average value of the dimensions b of the base of the pyramids.

40. The device according to claim 39, wherein less than 10% of the surface of the crystalline silicon is covered with pyramids having sub-micrometric dimensions and more than ⅔ of the surface of the crystalline surface is covered with pyramids, for which the dimensions b of the base are such that bε b̅±2.5 μm.

41. The device according to claim 38, wherein said crystalline silicon substrate has, between the pyramids, valleys having a rounded bottom.

42. The device according to claim 41, wherein said rounded bottom of the valleys has a radius of curvature greater than 0.005 μm, preferably comprised between 0.05 μm and 15 μm.

43. A photoelectric device with heterojunctions comprising a crystalline silicon substrate surface and at least one amorphous or microcrystalline silicon layer, wherein epitaxy has been limited during the growth of said amorphous or microcrystalline silicon on said crystalline silicon substrate, wherein said textured crystalline silicon substrate has at its surface pyramids having a regular layout such that less than 20% of the surface of the crystalline silicon is covered with pyramids having sub-micrometric dimensions and more than at least half of the surface of the crystalline silicon is covered with pyramids, for which the dimensions b of the base are such that bε b̅±5 μm, wherein b̅ is the average value of the dimensions b of the base of the pyramids, and wherein b is strictly greater than 1 μm.

44. The device according to claim 43, wherein less than 10% of the surface of the crystalline silicon is covered with pyramids having sub-micrometric dimensions and more than ⅔ of the surface of the crystalline surface is covered with pyramids, for which the dimensions b of the base are such that bε b̅±2.5 μm.

45. The device according to claim 43, wherein said crystalline silicon substrate has, between the pyramids, valleys having a rounded bottom.

46. The device according to claim 45, wherein said rounded bottom of the valleys has a radius of curvature greater than 0.005 μm, preferably comprised between 0.05 μm and 15 μm.
